(19) United States
(12) Patent Application Publication
(10) Pub. No.: US 2020/0163257 A1
(43) Pub. Date: May 21, 2020

(54) MICRO-AXIAL PUMP FOR SERVERS

(71) Applicant: HEWLETT PACKARD ENTERPRISE DEVELOPMENT LP, Houston, TX (US)

(72) Inventors: John Franz, Tomball, TX (US); Tahir Cader, Spokane Valley, WA (US); Harvey Lunsman, Chippewa Falls, WI (US)

(21) Appl. No.: 16/194,259

(22) Filed: Nov. 16, 2018

(51) Int. Cl. H05K 7/20

(52) U.S. Cl. CPC H05K 7/20763; H05K 7/20272; H05K 7/20836

(57) ABSTRACT

A device including a circuit component that dissipates heat and a cooling loop thermally coupled to the circuit component, is provided. The cooling loop includes an inlet port configured to receive a cooling fluid, a first axial pump disposed along a fluid flow channel and configured to move the cooling fluid axially through the fluid flow channel in the cooling loop at a specified flow rate, and an outlet port configured to transfer the cooling fluid out of the cooling loop, wherein the specified flow rate is adjusted according to one or more parameters.

### BACKGROUND

Systems for cooling circuit boards for high power demanding computing applications (e.g. computer processing unit—CPU—farms in computer servers, datacenters and the like) use cooling loops powered by bulky pumps having limited capacity and that are difficult to install and replace when they malfunction. Typically, these pumps involve centrifugal systems having form factors that are difficult to integrate in the highly compact racks used for computationally intensive servers.

### BRIEF DESCRIPTION OF THE DRAWINGS

The accompanying drawings, which are included to provide further understanding and are incorporated in and constitute a part of this specification, illustrate disclosed embodiments and together with the description serve to explain the principles of the disclosed embodiments. In the drawings:

FIG. 1A illustrates a circuit board including an axial pump in a cooling loop for heat transfer, according to some embodiments.

FIG. 1B shows a closer view of a portion of a circuit board including an axial pump in a cooling loop for heat transfer, according to some embodiments.

FIG. 1C illustrates a circuit board including a pump system in a cooling loop for heat transfer, according to some embodiments.

FIG. 2A illustrates a pumping system using axial pumps fluidically coupled in series, according to some embodiments.

FIG. 2B illustrates a pumping system using axial pumps fluidically coupled in parallel, according to some embodiments.

FIG. 3 illustrates a printed circuit board having multiple devices, according to some embodiments.

FIG. 4 illustrates a printed circuit board having multiple devices including a thermal management tool, according to some embodiments.

FIG. 5 is a flow chart illustrating steps in a method for making a circuit board including a pump system for cooling, according to some embodiments.

In the figures, elements and steps denoted by the same or similar reference numerals are associated with the same or similar elements and steps, unless indicated otherwise.

### DETAILED DESCRIPTION

In the following detailed description, numerous specific details are set forth to provide a full understanding of the present disclosure. It will be apparent, however, to one ordinarily skilled in the art, that the embodiments of the present disclosure may be practiced without some of these specific details. In other instances, well-known structures and techniques have not been shown in detail so as not to obscure the disclosure.

### General Overview

Continuous cooling system designs are desirable in current computational applications involving rapidly increasing device power levels. For liquid-cooled servers and racks, greater fluid flow rates are desirable to handle higher power levels. In some embodiments, without limitation, the cooling fluid of choice is water. The desire for higher flow rates tends to increase the overall size of the cooling system. However, at the node level (e.g., for network servers), larger cooling components may use valuable space in the server. Embodiments as disclosed herein provide a solution to the above problem by including axial pumps to increase pumping capacity. These pumps also enable handling higher pressure drops across the cooling loop and better flow control at the node level. Further, embodiments as disclosed herein enable manufacturers to extend the lifetime of a cooling infrastructure, to minimize the use of valuable server space, and to scale with device power.

In a first embodiment, a device as disclosed herein includes a circuit component that dissipates heat, and a cooling loop thermally coupled to the circuit component. The cooling loop includes an inlet port configured to receive a cooling fluid, a first axial pump disposed along a fluid flow channel and configured to move the cooling fluid axially through the fluid flow channel in the cooling loop at a specified flow rate, and an outlet port configured to transfer the cooling fluid out of the cooling loop, wherein the specified flow rate is adjusted in accordance with any one of multiple parameters or combinations thereof.

In a second embodiment, a system includes multiple servers arranged in a rack, each server comprising a device having at least one circuit component configured to perform electronic operations and dissipate a heat. The device includes a cooling loop thermally coupled to the circuit component. The cooling loop includes an inlet port configured to receive a cooling fluid, an axial pump disposed along a fluid flow channel and configured to move the cooling fluid axially through the fluid flow channel in the cooling loop at a specified flow rate, and an outlet port configured to remove the cooling fluid from the cooling loop. The specified flow rate is adjusted according to the heat dissipated by the circuit component, wherein a first axial pump for a first device in a first server is configured to operate at a first flow rate based on a first server activity, and a second axial pump for a second server is configured to operate at a second flow rate based on a second server activity.

In another embodiment, a method, includes identifying a first power dissipation of a first device, wherein the first device is placed on a circuit board. The method also includes arranging a flow path disposed on the circuit board to overlap with at least a portion of the first device, wherein the flow path is configured to enter the circuit board from an input port and to leave the circuit board from an output port, and determining a flow rate of a first axial pump to transfer the first power dissipation of the first device through the output port. The method also includes fluidically coupling the first axial pump along a flow axis of the flow path, and placing a second device on the circuit board based on a location of the first device, and on the flow path.

In yet another embodiment, a device includes a first means for storing instructions, and a second means for executing the instructions causing the device to perform a method. The method includes identifying a first power dissipation of a first device, wherein the first device is placed on a circuit board. The method also includes arranging a flow path disposed on the circuit board to overlap with at least a portion of the first device, wherein the flow path is configured to enter the circuit board from an input port and to leave the circuit board from an output port, and determining a flow rate of a first axial pump to transfer the first power dissipation of the first device through the output port. The method also includes fluidically coupling the first axial pump along a flow axis of the flow path, and placing a second device on the circuit board based on a location of the first device, and on the flow path.

Power levels for devices such as CPUs, graphic processing units (GPUs) and application specific integrated circuits (ASICs) are already high, and increasing rapidly as computer technology improves and applications proliferate. For example, a CPU in a server may consume up to 200 W, or more, of electrical power. In some embodiments, CPUs that reach 300 W of power consumption and more may be soon realized. GPUs have an even higher power consumption rate (e.g., currently 300 W and reaching 400 W and more in the near future). ASICs for network switches are at about 150 W, and increasing. The desired power consumption increases rapidly for High Performance Computing (HPC) and Artificial Intelligence (AI) applications. In such areas, the majority of platforms that deploy these devices are water-cooled. As device power scales up, the cooling loops (e.g., cooling loops) in the platforms desirably scale proportionally. In some embodiments, internal tubing diameters of ⅛ inch may suffice for water-cooled platforms, higher diameters (e.g., internal tubing diameters of 3/16 inch or even ¼ inch) are desirable to avoid higher pressure drop (undesirable due to turbulence, vibration and instability). However, as the internal diameter (ID) of the tubing increases, so does the outside diameter (ODs) and the bend radii for the tubing, along with the sizes of the quick disconnects (QDs), hose barbs, and other fluid fixtures. Accordingly, the cooling loop hardware takes increasing amounts of valuable server space. Embodiments disclosed herein use axial pumps for server-level deployment to deploy the same cooling loop for multiple generations of servers, while scaling with device power levels.

It is understood that other configurations of the subject technology will become readily apparent to those skilled in the art from the following detailed description, wherein various configurations of the subject technology are shown and described by way of illustration. As will be realized, the subject technology is capable of other and different configurations and its several details are capable of modification in various other respects, all without departing from the scope of the subject technology. Accordingly, the drawings and detailed description are to be regarded as illustrative in nature and not as restrictive.

### Example System Architecture

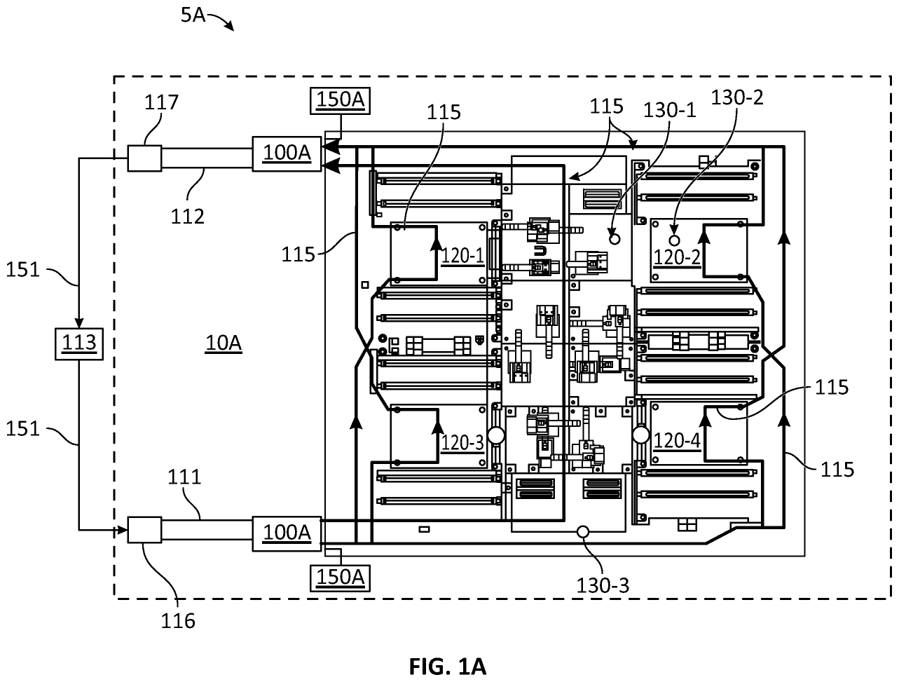

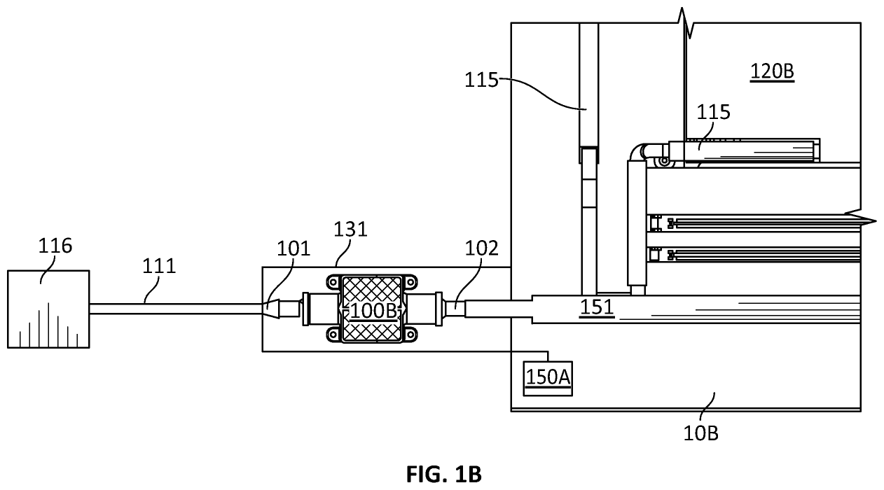

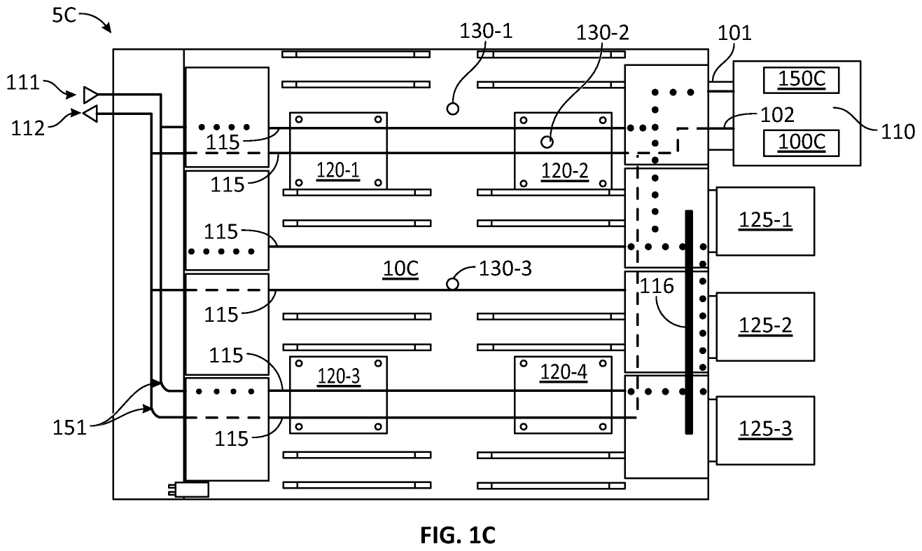

FIG. 1A illustrates a computing device 5A (e.g., a server node) that includes a circuit board 10A and at least one axial pump 100A in a cooling loop 115 for heat transfer, according to certain aspects of the disclosure. In some embodiments, and without limitation, axial pump 100A may be referred to as a “micro axial pump” based on the relative dimensions of the device compared to other dimensions in the environment where the pump operates. The specific denomination of “axial pump” or “micro axial pump” is interchangeable and not-limiting, in the context of the present disclosure. Cooling loop 115 may include a supply port 116 through which a cooling fluid 151 enters cooling loop 115, a return port 117 through which cooling fluid 151 exists cooling loop 115, and any number of coolant lines, cold plates, and/or other liquid cooling components that form one or more coolant flow paths that communicably connect supply port 116 to return port 117. Supply port 116 and return port 117 may include, for example, liquid couplings or connectors, such as hose barb connectors, clamped hose connectors, dry disconnect liquid connectors, blind mate liquid connectors, and the like. Cooling loop 115 includes multiple fluid flow channels arranged in a network and one or more axial pumps 100A between the supply port 116 and the return port 117. Each of axial pumps 100A is disposed along the fluid flow channels and are configured to move cooling fluid 151 axially through the fluid flow channel at a specified flow rate.

In some embodiments, a first axial pump 100A may be disposed adjacent to supply port 116, and a second axial pump 100A may be disposed adjacent to return port 117. This configuration facilitates removal and replacement of axial pumps 100A, in some cases obviating the need for a technician to remove the entire circuit board 10A and replace the pump, or remove an entire server rack or other encasing. In some embodiments, circuit board 10A may include only one, two, or more than two axial pumps 100A, each coupled to a fluid flow channel in cooling loop 115 either in series or in parallel (or both in series and in parallel). In some embodiments of computing device 5A, at least one of axial pumps 100A may be attached to circuit board 10A.

Cooling fluid 151 may be received by supply port 116 from a larger liquid cooling system 113 into which cooling loop 115 is integrated, and may be returned by return port 117 to liquid cooling system 113. For example, a supply line 111 may be connected to supply port 116 and a return line 112 may be connected to return port 117. In some embodiments supply line 111 and return line 112 may include a flexible hose and a connector. In some embodiments, a larger liquid cooling system 113 may include a heat exchanger (not illustrated) to remove heat from cooling fluid 151. For example, the liquid cooling system 113 may include a rack-level liquid cooling system, a row-level liquid cooling system, a datacenter-level liquid cooling system, etc.

Cooling loop 115 is configured to enable cooling fluid 151 to absorb heat generated by different circuit components 120-1, 120-2, 120-3, and 120-4 (collectively referred to, hereinafter, as “circuit components 120”) in circuit board 10A. Accordingly, in some embodiments the fluid flow channels in cooling loop 115 are placed on top of circuit components 120 to make thermal contact with the circuit component. Circuit components 120 may include processor circuits and memory circuits and combinations thereof. Processor circuits may include application specific integrated circuits (ASICs) and other specialized devices. Memory circuits may include random access memory (RAM) devices, such as dynamic RAM (DRAM), static RAM (SRAM), solid state devices (SSD), flash memories, and the like. Cooling loop 115 includes a flow path disposed on circuit board 10A, and configured to overlap at least partially with a portion of at least one of circuit components 120. More generally, and without any limitation, cooling loop 115 may be configured to transfer heat from any heat generating components on circuit board 10A.

Further, cooling loop 115 may include various components, such as supply lines, cold plates, and the like, through which cooling fluid 151 flows and that are thermally coupled to heat generating circuit components 120. Thus, heat generated by circuit components 120 is transferred to cooling fluid 151, thereby cooling circuit components 120 and heating cooling fluid 151. The heat transferred to cooling fluid 151 is then transported out of computing device 5A when cooling fluid 151 flows out of cooling loop 115. The heat transferred out of computing device 5A by cooling fluid 151 may ultimately be removed from cooling fluid 151 by the liquid cooling system 113 (e.g., via a heat exchanger or other cooling mechanism).

Axial pumps 100A are configured to move cooling fluid 151 axially through a fluid flow channel in cooling loop 115 at a specified flow rate. In that regard, axial pumps 100A may include at least one magnetically driven propeller embedded within cooling fluid 151. In some embodiments, a controller 150A is coupled to axial pump 100A to adjust the specified flow rate so as to transfer a desired amount of heat from one of circuit components 120 to return line 112. Controller 150A may be a commercially available pump controller. In some embodiments, controller 150A includes a general purpose processor executing instructions, such as an application-specific integrated circuit (ASIC), a field-programmable gate array (FPGA), a complex programmable logic device (CPLD), or other dedicated circuit. In some embodiments, controller 150A may include a baseboard management controller (BMC) of a network server, or any combination of the above.

In some embodiments, controller 150A is configured to control a flow rate of axial pump 100A based upon measured parameters. Some of the measured parameters used by controller 150A may include water temperature, water flow rate, device temperature and power consumption, air temperature, applications running (or scheduled to be run) in circuit board 10A, and the like. As such, controller 150A may include one or more digital and analog inputs. In some embodiments, controller 150A is a commercially available controller. In some embodiments, controller 150A may be a custom controller. Further, in some embodiments, controller 150A includes a small printed circuit board (PCB) attached to axial pump 100A. In some embodiments, controller 150A may be part of, or coupled with a board management controller for circuit board 10A, and may further be configured to interface with an “integrated lights out” (iLO) system in a server.

In that regard, circuit board 10A may also include temperature sensors 130-1, 130-2 and 130-3 (collectively referred to, hereinafter, as “temperature sensors 130”), configured to measure temperature at different points. For example, a first temperature sensor 130-1 may be configured to measure the temperature of the printed circuit board (PCB) away from circuit components 120. In addition, a second temperature sensor 130-2 may be configured to measure the temperature of at least one of circuit components 120. Furthermore, a third temperature sensor 130-3 may be placed in thermal contact with at least one of supply line 111 or return line 112, to measure the temperature of the cooling fluid. The flow rate of any one of axial pumps 100A may be specified according to a power dissipation of a first device in a circuit board, and the pre-determined temperature is selected based on a temperature of the circuit board. For example, temperature sensor 130-3 may detect that one of the temperature of return line 112, a temperature of one of circuit components 120, or a PCB temperature, is higher than a pre-selected threshold. Under these circumstances, controller 150 may execute instructions to cause axial pump 100A to increase its flow rate accordingly, so as to reduce the temperature of at least one of the PCB, the fluid, or the circuit components 120.

More generally, multiple parameters can be used by controller 150A to adjust the flow rate of axial pump 100A. Such parameters may include temperature of cooling fluid 151, flow rate, pressure drop (e.g., between supply port 116 and return port 117), device temperature, device power consumption, pre-scheduled workload, and the like. In addition to temperature measurements, controller 150A may have access to numerous parameters from the environment of circuit board 10A (e.g., server, chassis, rack, other racks, data center, and the like).

In some embodiments, and without any limitation, axial pumps 100A may include the following dimensions: a diameter of ˜7 mm; a length of ˜70 mm; a pump and motor length of about ˜35 mm; a pump impeller length ˜35 mm, and a magnetic drive motor with external controller and power. In some embodiments, any one of axial pumps 100A may be about 45 mm in length, 25 mm wide, and 13 mm tall, for a total volume of less than about 15 cm³ (or about 1 in³) versus a volume of ˜5 in³ (2.5″ diameter −6.25 cm−, 1″ tall −2.5 cm−) for a centrifugal pump transversal to the flow axis. In some embodiments, a pump capacity of 51/min (1.3 gallons per minute-gpm) at a pressure differential of ˜1.7-2 pounds per square inch differential (psid).

In some embodiments, axial pumps 100A can deliver twice the flow (or even up to 10×, or more) and three-times the pressure differential, at ⅕th the volume of a competing centrifugal pump, or even less. Other embodiments may vary in the flow and pressure capabilities, but generally these parameters are higher (e.g. multiple times higher) for axial pumps relative to centrifugal pumps, and at lower volume sizes, at comparable power consumption.

Tables I and II are a result of the analysis of the heat transfer benefits that could be achieved using an axial pump at the server level. For the model, a simple cylindrical tube was assumed (analogous to a micro channel in a cold plate), with heat applied to the external surface and water flowing on the inside. Tables I and II illustrate solutions for the heat transfer coefficients (HTCs) achievable at various flow rates, then use these HTCs to quantify the amount of heat that can be removed. For Table I, the model parameters were adjusted to match the pump capability, and the heat transfer coefficient was obtained. For this part of the analysis, only 10 W was applied to the tube wall, and because of the 170% increase in heat transfer coefficient with the axial pump, the associated wall surface temperature was lower. For the second part of the analysis (cf. Table II), the HTCs solved for in the first part of the analysis were used and the heat applied to the tube wall adjusted, until a constant surface temperature of 25 C was achieved. For this part of the analysis, the axial pump results in a 470% increase in the heat transfer from the tube wall, as compared to a comparable centrifugal pump.

Axial pumps 100A extends the life of computing device 5A (e.g., a server, a server rack and a row cooling infrastructures thereof), while scaling with device powers. Embodiments as illustrated in FIG. 1 may include a booster pump to preserve an existing infrastructure, or can be designed for an entirely new infrastructure. Further, axial pumps 100A provides node-level flow control that translates to savings at the rack level, which is particularly important for future exa-scale computing systems.

Further, some embodiments maintain the size of the server cooling loop components (e.g., tube diameters, quick disconnects, hose barbs, and the like) as the device powers scale higher, thereby minimizing the use of valuable server space.

TABLE I
Heat Transfer Coefficient (HTC) Analysis

| | Flow Rate | Pressure | HTC | Reynolds |
|---|---|---|---|---|
| Pump Type | (gpm) | Differential (PSI) | (W/m²K) | No. |
| Centrifugal | 0.11 | 0.63 | 18,181 | 5,756 |
| Micro-Axial | 1.32 | 1.99 | 49,099 | 35,422 |
| % Improvement | | | 170 | |

TABLE II
Heat Extraction at Surface Temperature

| | Flow | Pressure | | | Heat | Surface |
|---|---|---|---|---|---|---|
| | Rate | Differential | HTC | Reynolds | Removed | Temperature |
| Pump Type | (gpm) | (PSI) | (W/m²K) | No. | (W) | (C.) |
| Centrifugal | 0.11 | 0.63 | 18,181 | 5,756 | 10 | 25 |
| Micro-Axial | 1.32 | 1.99 | 49,099 | 35,422 | 57 | 25 |
| % Improvement | | | | | 470 | |

FIG. 1B shows a closer view of a portion of a circuit board 10B including an axial pump 100B in a cooling loop for heat transfer, according to some embodiments. Circuit board 10B may be a component in a server node or any other computing device consistent with the present disclosure (e.g., computing device 5A), and axial pump 100B may be as any one of axial pumps 100A. A sheet metal structure 131 supports and couples axial pump 100B with supply line 111 and supply port 116. Axial pump 100B includes an inlet port 101 to receive cooling fluid 151 from upstream, and an outlet port 102 to emit the cooling fluid 151 downstream in the cooling loop 115. In some examples, the inlet port 101 of axial pump 100B may also serve as the supply port 116 of the cooling loop 115, while in other examples the inlet port 101 and the supply port 116 may be distinct components. A circuit component 120B (e.g., collectively identified together with any one of circuit components 120) is thermally coupled with cooling loop 115. In some embodiments, outlet port 102 includes a flow splitter to separate an outlet flow from axial pump 100B into two parallel paths directed to twin cooling loops 115 (e.g., when circuit board 10B includes two circuit boards sandwiched together). The flow rate of axial pump 100B may be specified by controller 150A, as described above in reference to axial pumps 100A.

FIG. 1C illustrates a system including a computing device 5C (e.g., server node) and a pump module 110 that can be inserted into (e.g., “hot plugged”) and removed from (e.g., “hot unplugged”) a cooling loop 115 of a circuit board 10C in computing device 5C for heat transfer, according to certain aspects of the disclosure. Pump module 110 includes inlet port 101 and outlet port 102 to provide flow of cooling fluid 151 to cooling loop 115 via at least one axial pump 100C, as disclosed herein (e.g., axial pumps 100A, and 100C). In the following, axial pumps 100A, 100B and 100C will be collectively referred to as “axial pumps 100.” Similarly to computing device 5A, cooling fluid 151, may be water to transfer heat dissipated by circuit components 120 through return line 112. Cooling fluid 151 flows by pressure from some other pump (e.g., a rack level pump) when pump module 110 is unplugged. When pump module 110 is plugged in, it supplements the rack level pump, providing extra pressure to increase the flow rate inside circuit board 10C. Circuit board 10C also includes temperature sensors 130 and circuit components 120, as discussed in detail above. Some embodiments may include multiple pump modules 110 such that an external pump is not needed to continue moving the fluid in the event a single pump module 110 is removed from service.

In addition to circuit components 120, computing device 5C may include hard drives 125, 125-2 and 125-3 (hereinafter, collectively referred to as “hard drives 125”), and a heat pipe 116. Heat pipe 116 may be thermally coupled to hard drives 125 (to extract heat therefrom). Heat pipe 116 may include a hollow metal tube with a porous interior surface, filled with a high thermal conductivity fluid. In some embodiments, heat pipe 116 may be fluidically de-coupled from cooling loop 115. However, cooling loop 115 may be thermally coupled to heat pipe 116, to extract heat therefrom.

Pump module 110 may be a “hot plug” deployment for one or more axial pumps (e.g., axial pumps 100) in circuit board 10C. Accordingly, pump module 110 may double, triple, or otherwise enhance the flow capacity provided by a single axial pump. In some embodiments, pump module 110 is provided as a separate module that can be plugged into or removed from computing device 5C as desired. A controller 150C may be configured to regulate the speed of operation of pump module 110 (cf. controller 150A). Accordingly, controller 150C may use temperature data provided by temperature sensors 130 to increase, decrease, or maintain the speed of operation of pump module 110, similarly to controller 150B. In some embodiments, controller 150C may also be configured to shut down, start up, or put on standby at least one of the axial pumps, based on at least one of a, or a combination thereof, desired heat dissipation, a detected malfunction, an alert condition, and the like.

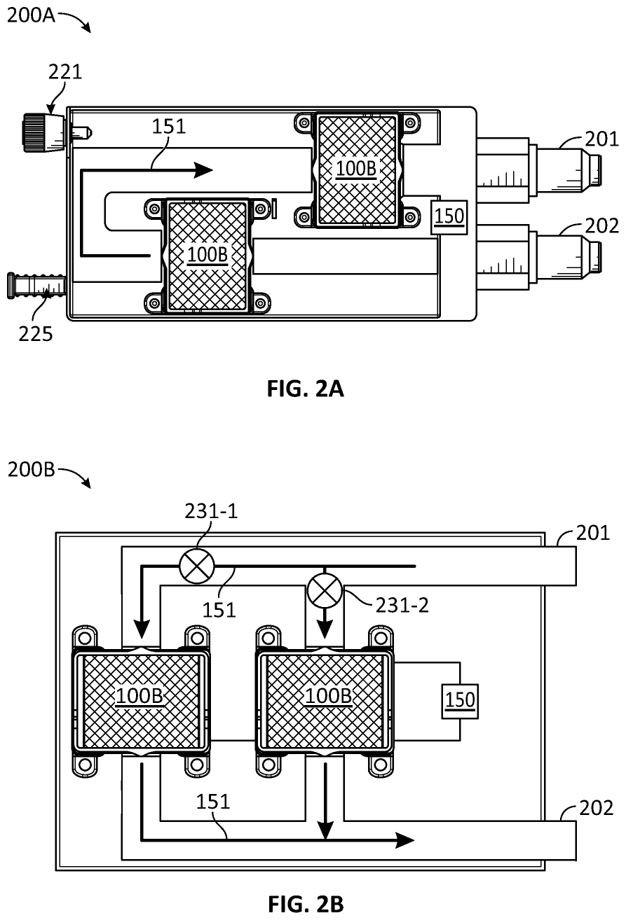

FIG. 2A illustrates a module 200A using two axial pumps 100B (hereinafter, collectively referred to as “axial pumps 100”) fluidically coupled in series, according to some embodiments. Module 200A could be used, for example, in circuit boards 10A, 10B or 10C, or in pump module 110 described above. Axial pumps 100 are configured to create a pressure differential between an inlet port 201 and an outlet port 202. Cooling fluid 151 circulates as shown, propelled by the pressure differential. Inlet port 201 and outlet port 202 may include a blind mate dripless fluid connector, and any other type of fluid connector. A retention feature 221 may hold module 200A in place (e.g., in a server rack, or in a server mount, and the like). In some embodiments, retention feature 221 may include a captive screw (as shown), a rotating latch, or any other similar component. A handle 225 may allow a user to easily remove module 200A from a circuit board.

A controller 150 sets and detects the operational conditions of axial pumps 100. In some embodiments, controller 150 is a plug-in accessory to module 200A that connects to module 200A via a connector edge. When controller 150 has a large form factor, then controller 150 may be mounted to a separate PCB coupled externally to module 200A. For a series coupling, it may be desirable to have axial pumps 100 operating at the same or similar speed. Accordingly, controller 150 may receive data from other sensors (e.g., temperature sensors 130) to control the speed of axial pumps 100, and provide data to external processors and systems (e.g., to a thermal management system). Controller 150 may be coupled to the rest of a circuit board (e.g., circuit boards 10A, 10B and 10C) via a connector system on a bottom side of module 200A (opposite to what is shown in FIG. 2A). In some embodiments, only one of axial pumps 100 may be operational at a given time in module 200A. Accordingly, the second axial pump 100 may be turned ‘on’ in case of failure of the first axial pump 100, or when an increased flow rate is specified. More generally, axial pumps 100 in module 200A may be configured to complement each other based on a desired flow rate for a cooling loop in a circuit board where module 200A is mounted.

FIG. 2B illustrates a module 200B using axial pumps 100B fluidically coupled in parallel, according to some embodiments. Module 200B could be used, for example, in the circuit boards 10A or in pump module 110 described above. Cooling fluid 151 flows between inlet port 201 and outlet port 202. In this configuration, controller 150 may desirably drive each of pumps 100 at a different speed or rate. Further, controller 150 may stop one of axial pumps 100 while it runs the other one. In some embodiments, controller 150 may start one of axial pumps 100 when the other one malfunctions, or stops operating. Moreover, in some embodiments controller 150 may alternate operation of axial pumps 100 according to a pre-selected schedule. Although not shown in FIG. 2B for simplicity, module 200B may also include a retention feature and a handle (e.g., retention feature 221 and handle 225). As described above in relation to module 200A, controller 150 may drive both, or only one of axial pumps 100, as specified by different operational conditions of a circuit board where module 200A is mounted. Modules 200A and 200B will be collectively referred to, hereinafter, as “modules 200.” In some embodiments, check valves 231-1 and 231-2 (hereinafter, collectively referred to as “check valves 231”) may be used to prevent reverse circulation when and if one of axial pumps 100 is not operational.

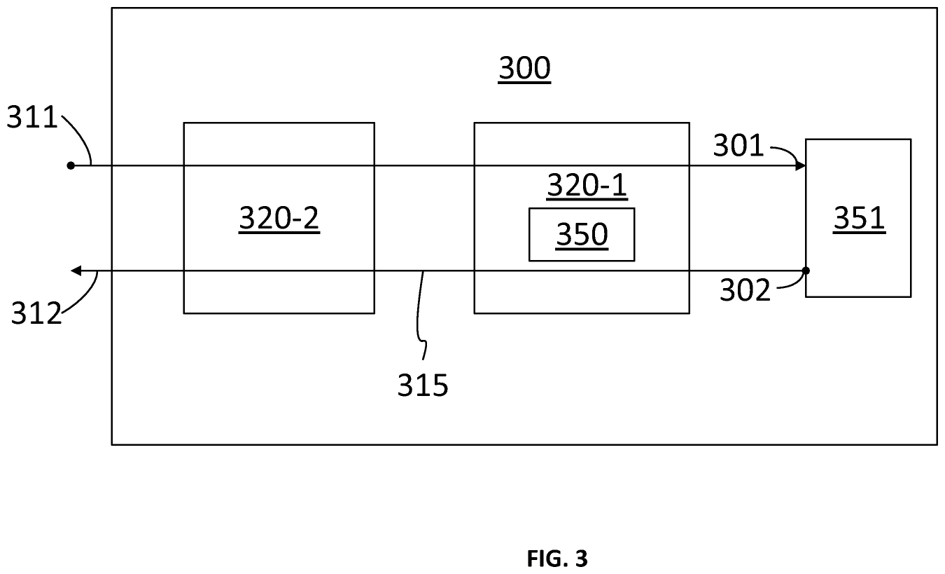

FIG. 3 illustrates a PCB 300 having circuit components 320-1 and 320-2 (hereinafter, collectively referred to as “circuit components 320”), according to some embodiments. At least one of circuit components 320 may include a memory circuit storing instructions (e.g., device 320-1). In some embodiments, one of circuit components 320 may include one or more processors configured to execute the instructions to cause a computer to perform a calculation and dissipate an amount of heat. A cooling loop 315 is configured to transfer the amount of heat out of printed circuit board 300 with a pump 351. Pump 351 includes an inlet port 301 configured to receive an inlet flow 311 and an outlet port 302 configured to provide outlet flow 312 to cooling loop 315.

Pump 351 may also include an axial pump configured to create a pressure differential between inlet port 301 and outlet port 302 (e.g., axial pumps 100). More generally, pump 351 may include any one of modules 110 or 200. A circuit component 320-1 may include a controller 350 coupled to pump 351 (e.g., to the first axial pump) and configured to adjust the pressure differential to transfer a pre-determined amount of heat from circuit components 320-1, 320-2, or both, to an outlet flow 312 at a pre-determined temperature. The pre-determined amount of heat is selected based on a power dissipation of circuit component 320-1, and the pre-determined temperature.

PCB 300 is a simple schematic illustrating some of the benefits that would result from deploying an axial pump at a server level (e.g., computing device 5A or 5C). For example, a typical rack-level server deployment results in an inlet water pressure of 20 psia, a flow rate of 0.5 gpm, and a pressure drop of 2 psia across the server. Future systems may deploy GPUs at power levels of 600 W each, or even more. Pump 351 may be a pump system including one or more axial pumps, obviating the need to change the server-level cooling loop parameters to allow for much higher flow rates to cool the higher power devices. In some embodiments pump 351 may be a pump system including one or more axial pumps in different configurations, wherein the same basic cooling loop infrastructure can be maintained. For example, while tube routing may change, the same or similar tube diameter and other components can be maintained since the axial pump will provide the capacity needed to increase flow velocity. Pump 350 also brings infrastructure benefits that will be seen at the rack and row levels. Using one or more axial pumps (e.g., pump 350), it is possible to control the flow at each node in a server rack. Current designs are geared towards “worst-case” server (e.g., the server in a server rack that is using the maximum amount of power and thus demands the maximum flow rate). Accordingly, current designs deliver desired flow rates to the entire server rack based on the worst-case server, even if another server in the server rack is sitting at idle. With an axial pump (e.g., pump 350), control of the flow rate at each individual node may result in significant savings at the rack level. For example, a server running at maximum power in the rack may use a flow rate of 0.5 gpm, while a server that is idle in the rack may use a flow rate of 0.2 gpm. Accordingly, a 47% may be saved in flow rate at the rack level by applying the differentiated flow rates to each node.

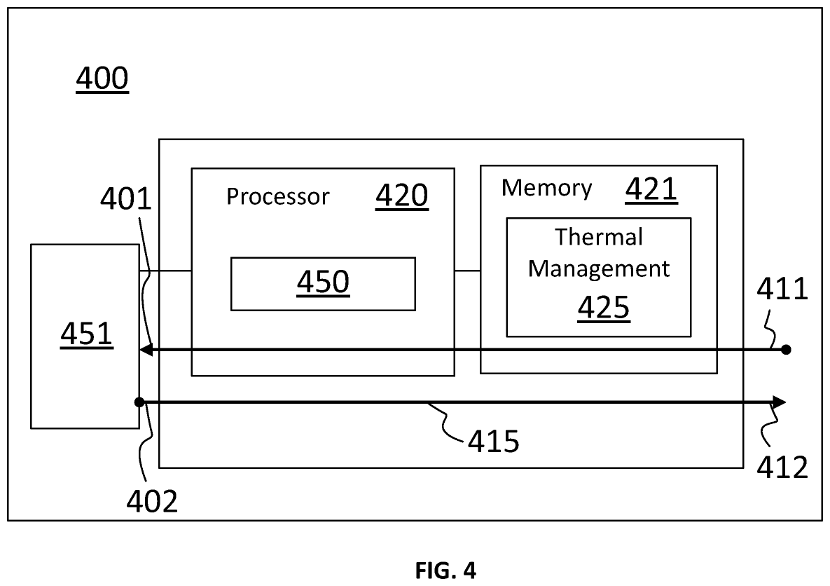

FIG. 4 illustrates a printed circuit board (PCB) 400 having a processor 420 and a memory 421, according to some embodiments. Memory 421 may include a thermal management tool 425 storing instructions to cause a controller 450 in processor 420 to control the speed and other operational parameters of pump 451. Controller 450 may also adjust the pressure differential between an inlet port 401 and an outlet port 402, to establish a specified flow rate in cooling loop 415. Accordingly, heat generated in processor 420, in memory 421, or both, is transferred from an inlet flow 411 to an outlet flow 412, at a pre-determined temperature. The flow rate is specified based on a power dissipation of processor 420 and memory 421. In some embodiments, the flow rate is specified based on a desired temperature for PCB 400 or any of the circuit components therein.

Pump 451 may include a first axial pump configured to create the pressure differential between inlet port 401 and outlet port 402 (e.g., any one of, or both axial pumps 100). Accordingly, a cooling fluid (e.g., cooling fluid 150) flows through a cooling loop 415 that overlaps, at least partially, processor 420 and memory 421. In some embodiments of PCB 400 the first axial pump in pump 451 may include an electro-magnetically activated propeller embedded with the inlet flow. In some embodiments, the cooling loop and one of processor 420 or memory 421 are disposed on PCB 400 according to the power dissipation of the device (e.g., processor 420 or memory 421) and a heat transfer capacity of pump 451.

In some embodiments of PCB 400, pump 451 may further include a second axial pump disposed in cooling loop 415 between inlet flow 411 and outlet flow 412. Accordingly, the second axial pump may be configured to complement the first axial pump based on the pressure differential. In some embodiments of PCB 400, the second axial pump may be fluidically coupled in series or in parallel with the first axial pump (e.g., modules 200), and configured to complement the first axial pump based on the pressure differential desired between inlet flow 411 and outlet flow 412.

In some embodiments of PCB 400, controller 450 is configured to receive the temperature of the circuit board from a temperature sensor disposed on PCB 400 (cf. temperature sensor 130-1). In some embodiments of PCB 400, to specify the flow rate, controller 450 is further configured to receive a temperature of a device disposed on the circuit board from a temperature sensor disposed on the device (e.g., processor 420, memory 421, circuit components 120 and sensor 130-2).

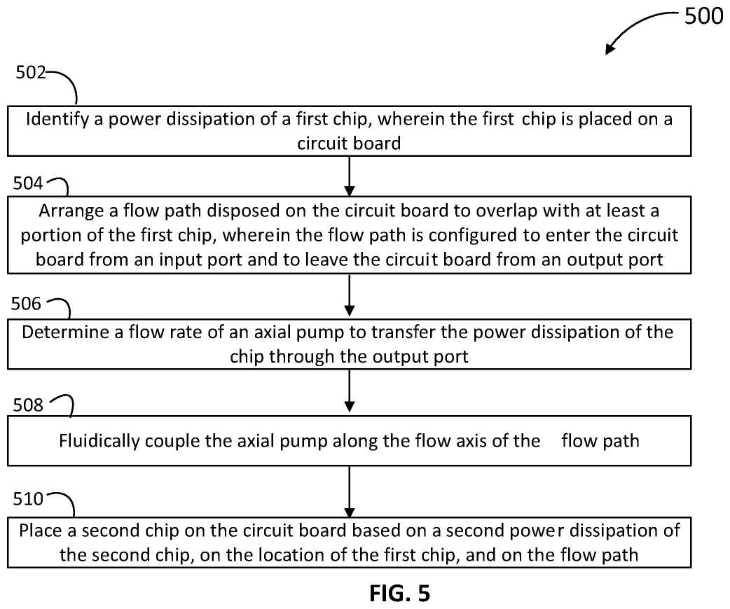

FIG. 5 is a flow chart illustrating steps in a method 500 for making a circuit board including a pump system for cooling, according to some embodiments. Methods consistent with the present disclosure may include at least one, but not all, of the steps in method 500. Further, methods consistent with the present disclosure may include one or more of the steps in method 500 performed in a different order, or performed overlapping in time, or almost simultaneously.

Step 502 includes identifying a power dissipation of a first device, wherein the first circuit component device is placed on a circuit board.

Step 504 includes arranging a flow path disposed on the circuit board to overlap with at least a portion of the first device, wherein the flow path is configured to enter the circuit board from an input port and to leave the circuit board from an output port.

Step 506 includes determining a flow rate of an axial pump to transfer the power dissipation of the first device through the output port.

Step 508 includes fluidically coupling the axial pump along a flow axis of the flow path.

Step 510 includes placing a second device on the circuit board based on a second power dissipation of the second device, on the location of the first device, and on the flow path. In some embodiments, step 510 further includes fluidically coupling a second axial pump along the flow axis of the flow path to complement the flow rate of the first axial pump based on the first power dissipation and the second power dissipation. In some embodiments, step 510 further includes disposing at least one temperature sensor thermally coupled to the first device or to the second device.

Multiple variations and modifications are possible and consistent with embodiments disclosed herein. Although certain illustrative embodiments have been shown and described here, a wide range of modifications, changes, and substitutions is contemplated in the foregoing disclosure. While the above description contains many specifics, these should not be construed as limitations on the scope of the embodiment, but rather as exemplifications of one or another preferred embodiment thereof. In some instances, some features of the present embodiment may be employed without a corresponding use of the other features. Accordingly, it is appropriate that the foregoing description be construed broadly and understood as being given by way of illustration and example only, the spirit and scope of the embodiment being limited only by the appended claims.

1. A device, comprising:
a circuit component that dissipates heat; and
a cooling loop thermally coupled to the circuit component, the cooling loop comprising:
an inlet port configured to receive a cooling fluid;
a first axial pump disposed along a fluid flow channel and configured to move the cooling fluid axially through the fluid flow channel in the cooling loop; and
an outlet port configured to transfer the cooling fluid out of the cooling loop, wherein a flow rate of the axial pump is adjusted in accordance with any one of multiple parameters.

2. The device of claim 1, wherein the cooling loop further comprises a controller coupled to the first axial pump, the controller configured to adjust the specified flow rate according to a desired parameter, wherein the desired parameter may include a water temperature, a device temperature, a power consumption, an air temperature, an executing application, or an application scheduled to be executed.

3. The device of claim 1, further comprising a second axial pump arranged with the first axial pump in a removable module, wherein the removable module is fluidically coupled with the cooling loop via a module inlet and a module outlet, and is electrically coupled with the device via a controller.

4. The device of claim 1, further comprising a second axial pump disposed along a second fluid flow channel in the cooling loop to complement the specified flow rate, and wherein the second fluid flow channel is fluidically coupled in series with the fluid flow channel having the first axial pump.

5. The device of claim 1, further comprising a second axial pump disposed along a second fluid flow channel in the cooling loop to complement the specified flow rate, and wherein the second fluid flow channel is fluidically coupled in parallel with the fluid flow channel having the first axial pump.

6. The device of claim 1, wherein the circuit component is a node in a server rack, and the specified flow rate is determined based on at least one parameter of the server rack.

7. The device of claim 1, wherein the first axial pump includes an electro-magnetically activated propeller embedded with the cooling fluid.

8. The device of claim 1, further comprising a controller and a temperature sensor, wherein the controller is configured to determine the specified flow rate based on a value provided by the temperature sensor.

9. The device of claim 1, further comprising a heat pipe thermally coupled to a second circuit component and configured to transfer heat from the second circuit component to the cooling fluid, and to be thermally coupled with the cooling loop.

10. The device of claim 1, wherein the first axial pump is disposed adjacent to one of the inlet port or the outlet port, to facilitate removal and replacement, the device further comprising a second axial pump adjacent to one of the inlet port or the outlet port.

11. A system, comprising:
multiple servers arranged in a rack, each server comprising a device having at least one circuit component configured to perform electronic operations and dissipate a heat, wherein the device includes:
a cooling loop thermally coupled to the circuit component, the cooling loop comprising:
an inlet port configured to receive a cooling fluid;
an axial pump disposed along a fluid flow channel and configured to move the cooling fluid axially through the fluid flow channel in the cooling loop at a flow rate; and
an outlet port configured to remove the cooling fluid from the cooling loop, wherein the flow rate is adjusted in accordance with any one of multiple parameters, wherein
a first axial pump for a first device in a first server is configured to operate at a first flow rate, and a second axial pump for a second server is configured to operate at a second flow rate.

12. The system of claim 11, further comprising a second device in a second server, the second device comprising a second axial pump configured to move a second cooling fluid in a second cooling loop at a second flow rate.

13. The system of claim 11, wherein, in the device, the cooling loop further comprises a controller coupled to the first axial pump, the controller configured to adjust the flow rate according to a desired parameter of the device, wherein the desired parameter may include a water temperature, a device temperature, a power consumption, an air temperature, an executing application in the device, or an application scheduled to be executed by the device.

14. The system of claim 11, wherein the device further comprises a second axial pump arranged with the first axial pump in a removable module that is fluidically coupled with the cooling loop via a module inlet and a module outlet, and is electrically coupled with the device via a controller.

15. The system of claim 11, further comprising a second axial pump disposed in the cooling loop between the inlet port and the outlet port, the second axial pump configured to complement the first axial pump based on flow rate.

16. The system of claim 11, wherein the flow rate for each axial pump in each device for each server is configured to provide a flow rate based on a power consumption by each server.

17. The system of claim 11, further comprising a centralized controller configured to provide the first flow rate for the first axial pump and the second flow rate for the second axial pump.

18. The system of claim 11, wherein the device is one of a memory circuit or one or more processors, and wherein the cooling loop and the first device are disposed on a circuit board according to the heat dissipated by the circuit component and a heat transfer capacity of the axial pump.

19. A method, comprising:
identifying a first power dissipation of a first device, wherein the first device is placed on a circuit board;
arranging a flow path disposed on the circuit board to overlap with at least a portion of the first device, wherein the flow path is configured to enter the circuit board from an input port and to leave the circuit board from an output port;
determining a flow rate of a first axial pump to transfer the first power dissipation of the first device through the output port;
fluidically coupling the first axial pump along a flow axis of the flow path, wherein the first axial pump moves a cooling fluid axially along the flow axis; and
placing a second device on the circuit board based on a second power dissipation of the second device, on a location of the first device, and on the flow path.

20. The method of claim 19, further comprising:
fluidically coupling a second axial pump along the flow axis of the flow path to complement the flow rate of the first axial pump based on the first power dissipation and the second power dissipation; and
disposing at least one temperature sensor thermally coupled to the first device or to the second device.
